(19) United States
(12) Patent Application Publication
(10) Pub. No.: US 2023/0220534 A1
(43) Pub. Date: Jul. 13, 2023

(54) MASK-INTEGRATED FRAME AND METHOD OF MANUFACTURING THE SAME

(71) Applicant: Olum Material Corporation, Yongin-si (KR)

(72) Inventors: Taek Yong JANG, Seongnam-si (KR); Byung Il LEE, Seongnam-si (KR); Young Ho LEE, Yongin-si (KR)

(21) Appl. No.: 17/842,335

(22) Filed: Jun. 16, 2022

(30) Foreign Application Priority Data
Jan. 7, 2022 (KR) 10-2022-0002884
Feb. 17, 2022 (KR) 10-2022-0020567
Mar. 23, 2022 (KR) 10-2022-0035858

(51) Int. Cl. C23C 14/04; H01L 51/56

(52) U.S. Cl. CPC C23C 14/042; H01L 51/56

(57) ABSTRACT

Proposed are a mask-integrated frame and a method of manufacturing the same. The mask-integrated frame used to deposit organic light-emitting diode (OLED) pixels on a semiconductor wafer includes a frame including an opening, a grid sheet connected onto the frame, having a circular edge, and including grids provided on at least the opening of the frame, and a mask connected onto the grid sheet, having a circular shape, and including mask patterns.

### CROSS-REFERENCE TO RELATED PATENT APPLICATIONS

This application claims the benefit of Korean Patent Application No. 10-2022-0002884, filed on Jan. 7, 2022, Korean Patent Application No. 10-2022-0020567, filed on Feb. 17, 2022, and Korean Patent Application No. 10-2022-0035858, filed on Mar. 23, 2022, respectively, in the Korean Intellectual Property Office, the disclosures of which are incorporated herein in their entireties by reference.

### BACKGROUND

### 1. Field of the Invention

The present invention relates to a mask-integrated frame and a method of manufacturing the same and, more particularly, to a mask-integrated frame used to deposit pixels on a semiconductor wafer and capable of precisely forming ultra-high-resolution mask patterns, and a method of manufacturing the same.

### 2. Description of the Related Art

As a pixel deposition technique in an organic light-emitting diode (OLED) manufacturing process, a fine metal mask (FMM) method for depositing organic materials at desired positions by placing a thin metal mask (or a shadow mask) in close contact with a substrate is commonly used.

In a general OLED manufacturing process, a thin film mask is produced and then is welded and fixed to an OLED pixel deposition frame, but the large-sized mask may not be easily aligned in the fixing process. Furthermore, in the process of welding and fixing the mask to the frame, the mask having an excessively small thickness and a large size may sag or warp due to the weight thereof.

Because even a small alignment error of 1 μm or less may lead to pixel deposition failure in an ultra-high-resolution OLED manufacturing process, a technology capable of preventing mask deformation, e.g., sagging or warping, and of ensuring precise mask alignment needs to be developed.

Currently, a microdisplay applied to virtual reality (VR) devices is attracting much attention. In order to display an image on the VR device immediately in front of a user's eyes, the microdisplay needs to have a screen size much smaller than those of general displays and to implement high image quality within the small screen. Therefore, mask patterns smaller than those used in a general ultra-high-resolution OLED manufacturing process, and more precise mask alignment before pixel deposition are required.

### SUMMARY

The present invention provides a mask-integrated frame capable of implementing ultra-high-resolution pixels of a microdisplay, and a method of manufacturing the same.

The present invention also provides a mask-integrated frame capable of improving stability of pixel deposition by ensuring precise mask alignment, and a method of manufacturing the same.

However, the scope of the present invention is not limited thereto.

According to an aspect of the present invention, there is provided a mask-integrated frame used to deposit organic light-emitting diode (OLED) pixels on a semiconductor wafer, the mask-integrated frame including a frame including an opening, a grid sheet connected onto the frame, having a circular edge, and including grids provided on at least the opening of the frame, and a mask connected onto the grid sheet, having a circular shape, and including mask patterns.

The grid sheet may include an edge connected onto the frame, a plurality of first grids extending in a first direction and including both ends connected to the edge, and a plurality of second grids extending in a second direction perpendicular to the first direction to cross the first grids, and including both ends connected to the edge.

First welds may be formed in at least portions of the edge to attach the grid sheet to the frame.

The mask may include a dummy connected onto the grid sheet, a plurality of cells provided at a center of the mask compared to the dummy, and including a plurality of mask patterns, and separators provided at the center of the mask compared to the dummy, and provided between the plurality of cells.

Second welds may be formed in at least portions of the dummy to attach the mask to the grid sheet.

The first and second grids may be provided under the separators.

Third welds may be formed in at least portions of the first and second grids to attach the first and second grids to the separators.

The third welds may be formed to protrude from a surface opposite to a surface where at least the first and second grids are in contact with the separators, and welding holes may be formed from the opposite surface in the first and second grids where the third welds are to be formed.

The mask may have a thickness of 2 μm to 12 μm, and the grid sheet may have a thickness of 20 μm to 50 μm.

The mask patterns may include first mask patterns at upper portions and second mask patterns at lower portions, the first mask patterns may have a thickness greater than a thickness of the second mask patterns, and both side surfaces of the first and second mask patterns may have a curvature.

Specific first and second grids from among the first and second grids may have a width greater than that of the other first and second grids.

According to another aspect of the present invention, there is provided a method of manufacturing a mask-integrated frame used to deposit organic light-emitting diode (OLED) pixels on a semiconductor wafer, the method including (a) connecting a grid sheet having a circular edge, onto a frame including an opening, wherein the grid sheet includes grids provided on at least the opening of the frame, and (b) connecting a mask having a circular shape and including mask patterns, onto the grid sheet.

The grid sheet may include an edge connected onto the frame, a plurality of first grids extending in a first direction and including both ends connected to the edge, and a plurality of second grids extending in a second direction perpendicular to the first direction to cross the first grids, and including both ends connected to the edge.

The step (a) may include (a1) placing the grid sheet in contact with the frame by loading, on the frame, a first template to which the grid sheet is adhered, and (a2) attaching the grid sheet to the frame by irradiating a laser beam onto at least portions of a region where the grid sheet is in contact with the frame.

In the step (a1), the first template to which the grid sheet is adhered may be provided by (1) adhering a grid metal film onto the first template including a surface on which a temporary adhesive member is formed, and (2) forming the grids by etching the grid metal film.

The mask may include a dummy connected onto the grid sheet, a plurality of cells provided at a center of the mask compared to the dummy, and including a plurality of mask patterns, and separators provided at the center of the mask compared to the dummy, and provided between the plurality of cells.

The step (b) may include (b1) placing the mask in contact with the grid sheet by loading, on the grid sheet, a second template to which the mask is adhered, and (b2) attaching the mask to the grid sheet by irradiating a laser beam onto at least portions of a region where the mask is in contact with the grid sheet.

In the step (b1), the second template to which the mask is adhered may be provided by (1) adhering a mask metal film onto the second template including a surface on which a temporary adhesive member is formed, and (2) forming a plurality of mask patterns by etching the mask metal film.

The method may further include attaching at least portions of the grids to the separators by irradiating a laser beam onto a surface opposite to a surface where the grids are in contact with the separators.

The step (2) may further include forming welding holes in the grids, and placing a surface of the grids opposite to a surface where the welding holes are formed, in contact with the mask, and attaching at least portions of the grids to the mask by irradiating a laser beam from the surface where the welding holes are formed.

### BRIEF DESCRIPTION OF THE DRAWINGS

The above and other features and advantages of the present invention will become more apparent by describing in detail embodiments thereof with reference to the attached drawings in which:

FIG. 1 is a perspective view of a mask-integrated frame according to an embodiment of the present invention;

FIG. 2 is a side cross-sectional view taken along A-A′ of FIG. 1;

FIG. 3 includes a plan view and a B-B′ side cross-sectional view showing connection between a grid sheet and a frame, according to an embodiment of the present invention;

FIG. 4 includes a plan view and an E-E′ side cross-sectional view of a mask according to an embodiment of the present invention;

FIGS. 5 to 8 include plan views and cross-sectional views showing a process of manufacturing a first template on which a grid sheet is supported, by adhering a grid metal film and forming the grid sheet on the first template, according to an embodiment of the present invention;

FIGS. 9 and 10 are cross-sectional views showing a process of connecting a grid sheet to a frame by loading, on the frame, a first template 50 on which the grid sheet is supported, according to an embodiment of the present invention.

FIGS. 11 to 13 include plan views and cross-sectional views showing a process of manufacturing a second template on which a mask is supported, by adhering a mask metal film and forming mask patterns on the second template, according to an embodiment of the present invention

FIGS. 14 to 16 include cross-sectional views showing a process of manufacturing a mask by forming mask patterns on a mask metal film, according to an embodiment of the present invention;

FIG. 17 includes cross-sectional views showing a process of manufacturing a mask by forming mask patterns on a mask metal film, according to another embodiment of the present invention;

FIGS. 18 and 19 are cross-sectional views showing a process of connecting a mask to a grid sheet by loading, on the grid sheet, a second template on which the mask is supported, according to an embodiment of the present invention;

FIG. 20 is a cross-sectional view showing connection between a mask and a grid sheet, according to various embodiments of the present invention;

FIG. 21 is a cross-sectional view of an organic light-emitting diode (OLED) pixel deposition apparatus using a mask-integrated frame, according to an embodiment of the present invention;

FIG. 22 includes a plan view and a B-B′ side cross-sectional view showing connection between a grid sheet and a frame, according to another embodiment of the present invention; and

FIG. 23 includes a plan view and an E-E′ side cross-sectional view of a mask according to another embodiment of the present invention.

### DETAILED DESCRIPTION

The following detailed description of the invention will be made with reference to the accompanying drawings illustrating specific embodiments of the invention by way of example. These embodiments will be described in sufficient detail such that the invention may be carried out by one of ordinary skill in the art. It should be understood that various embodiments of the invention are different but do not need to be mutually exclusive. For example, a specific shape, structure, or characteristic described herein in relation to an embodiment may be implemented as another embodiment without departing from the scope of the invention. In addition, it should be understood that positions or arrangements of individual elements in each disclosed embodiment may be changed without departing from the scope of the invention. Therefore, the following detailed description should not be construed as being restrictive and, if appropriately described, the scope of the invention is defined only by the appended claims and equivalents thereof. In the drawings, like reference numerals denote like functions, and lengths, areas, thicknesses, and shapes may be exaggerated for convenience's sake.

Hereinafter, the present invention will be described in detail by explaining embodiments of the invention with reference to the attached drawings, such that one of ordinary skill in the art may easily carry out the invention.

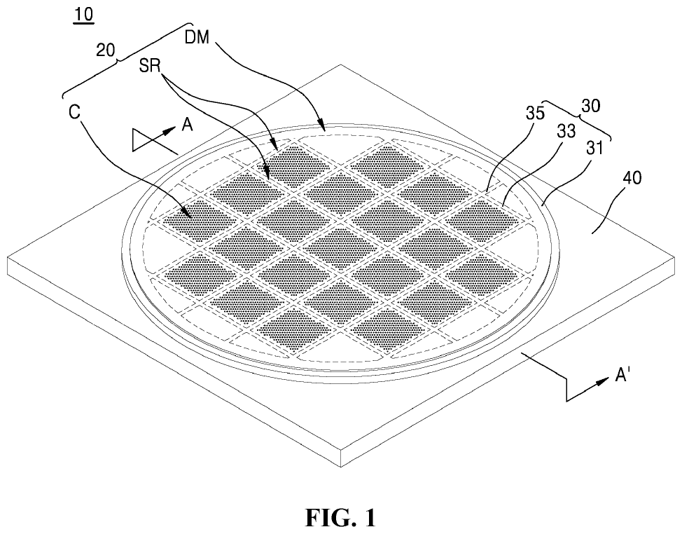

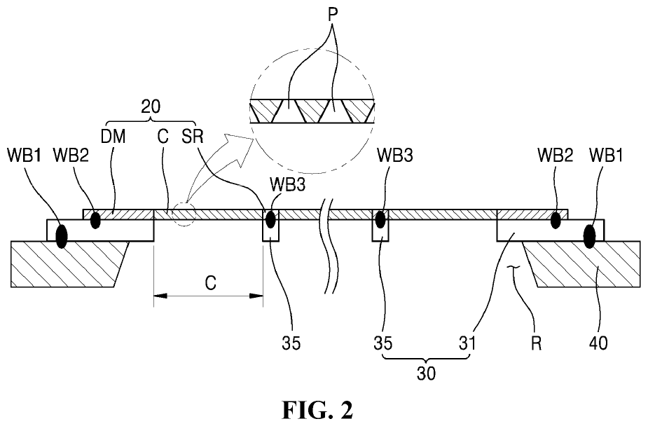

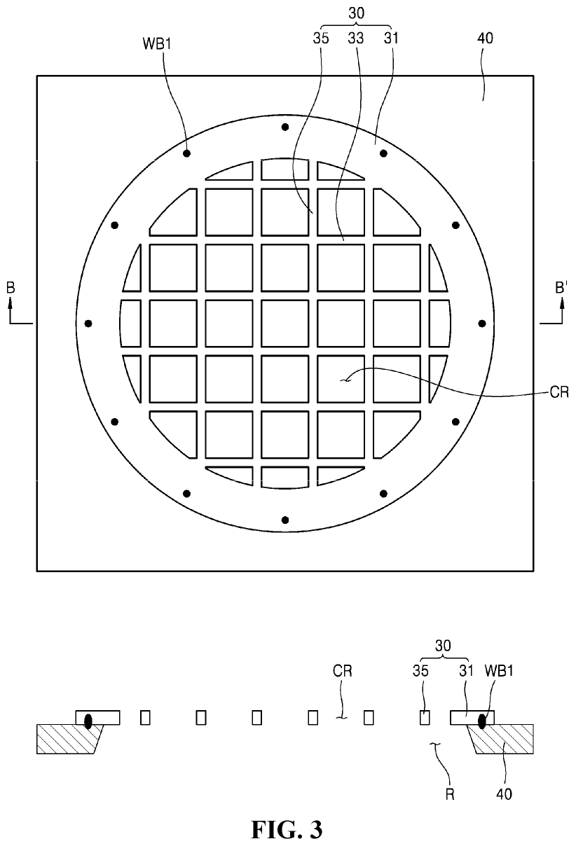

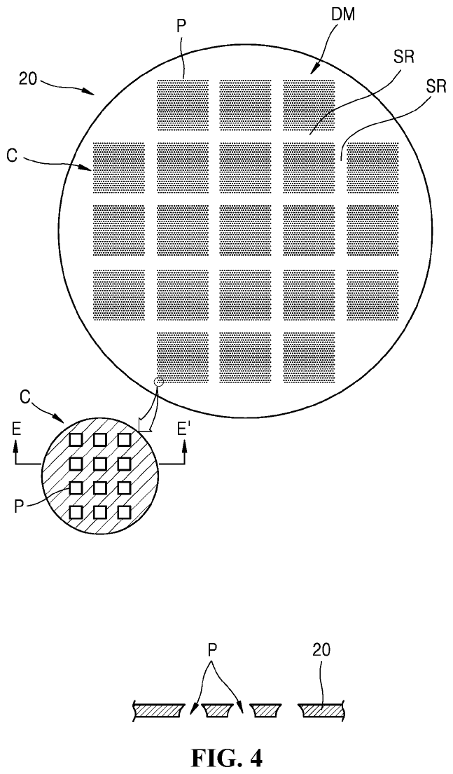

FIG. 1 is a perspective view of a mask-integrated frame 10 according to an embodiment of the present invention. FIG. 2 is a side cross-sectional view taken along A-A′ of FIG. 1. FIG. 3 includes a plan view and a B-B′ side cross-sectional view showing connection between a grid sheet 30 and a frame 40, according to an embodiment of the present invention. FIG. 4 includes a plan view and an E-E′ side cross-sectional view of a mask 20 according to an embodiment of the present invention.

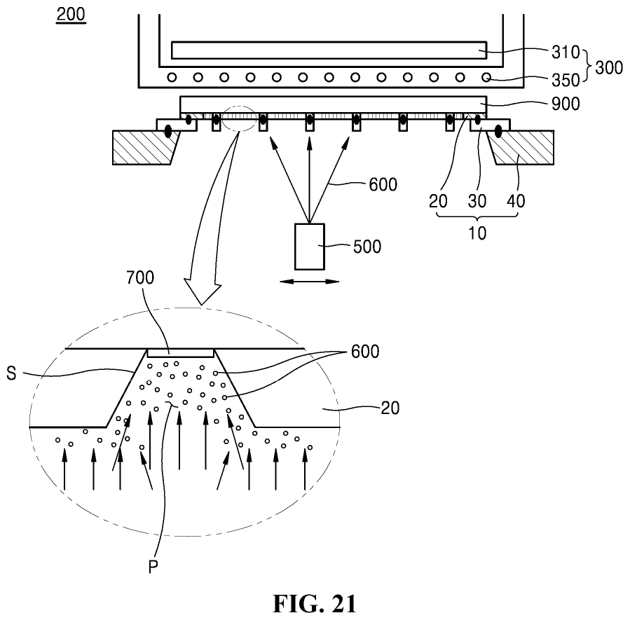

For a microdisplay currently applied to virtual reality (VR) devices, pixel deposition may be performed on a target substrate 900 (see FIG. 21), e.g., a semiconductor wafer or a silicon wafer, rather than a large-sized substrate. The microdisplay is located immediately in front of a user's eyes, and thus has a small screen size of about 1 to 2 inches rather than a large screen size. In addition, due to the location close to the user's eyes, the microdisplay needs to be implemented with a higher resolution.

Therefore, the present invention provides a method of manufacturing the mask-integrated frame 10, the method being capable of depositing ultra-high-resolution pixels on a 200 mm, 300 mm, or 450 mm semiconductor wafer target substrate 900 rather than a large-sized target substrate having a side length exceeding 1,000 m, and also provides the mask-integrated frame 10. For example, currently, quad high definition (QHD) refers to a resolution of 500 to 600 pixels per inch (PPI) and a pixel size of about 30 to 50 μm, and 4K ultra high definition (UHD) and 8K UHD refer to higher resolutions of up to 860 PPI and up to 1,600 PPI. A microdisplay directly applied to a VR device or a microdisplay attached to a VR device is aimed for an ultra-high resolution of about 2,000 PPI or higher, and has a pixel size of about 5 to 10 μm. Compared to a glass substrate, a semiconductor wafer or a silicon wafer may be finely and precisely processed by utilizing techniques developed in semiconductor processes, and thus may be employed as a substrate of a high-resolution microdisplay. The present invention is characterized by the mask-integrated frame 10 capable of depositing pixels on the above-described semiconductor wafer.

Referring to FIGS. 1 and 2, the present invention is characterized in that the mask 20 has a shape corresponding to the semiconductor (or silicon) wafer, to perform pixel deposition by using the semiconductor wafer as the target substrate 900 (see FIG. 21). When the shape of the mask 20 corresponds to the semiconductor wafer, it means that the mask 20 is the same in size and shape as the semiconductor wafer, or that the mask 20 is different in size and shape from the semiconductor wafer but is at least coaxial with the semiconductor wafer and mask patterns P are provided within the shape of the semiconductor wafer. The mask 20 having the shape corresponding to the semiconductor wafer is characterized by being integrally connected to the frame 40 to ensure precise mask alignment.

The mask-integrated frame 10 may include the mask 20, the grid sheet 30, and the frame 40. The grid sheet 30 may be attached to a portion of the surface of the frame 40. The mask 20 may be attached to a portion of the surface of the grid sheet 30. That is, the grid sheet 30 may be attached onto the frame 40, and the mask 20 may be attached onto the grid sheet 30.

Referring to FIGS. 1, 2, and 4, the mask 20 may include cells C, separators SR, and a dummy DM. In the mask 20, portions where the mask patterns P are formed without being in contact with the grid sheet 30 are called the cells C, portions provided between the cells C are called the separators SR, and a portion partially attached to the grid sheet 30 is called the dummy DM. Although the cells C, the separators SR, and the circular dummy DM are denoted by different names and symbols depending on the positions thereof, the cells C, the separators SR, and the dummy DM are not divided from each other but include the same material and are integrally connected to each other. In other words, the cells C, the separators SR, and the circular dummy DM are portions of the mask 20 which are simultaneously formed in a process such as rolling or electroforming. In the following description, the cells C, the separators SR, and the dummy DM may be used interchangeably with the mask 20.

The mask 20 may be made of Invar or Super Invar, and have a circular shape to correspond to the circular semiconductor wafer. The mask 20 may have a size equal to or greater than that of a 200 mm, 300 mm, or 450 mm semiconductor wafer.

In general, a mask has a rectangular or polygonal shape to correspond to a large-sized substrate. A frame also has a rectangular or polygonal shape to correspond to the mask, and the mask includes corners and thus stress may be concentrated on the corners. Because a different level of force is applied to portions of the mask on which stress is concentrated, the mask may be warped or distorted, which may lead to pixel alignment failure. Particularly, the concentration of stress on the corners of the mask needs to be avoided for an ultra-high resolution of 2,000 PPI or higher.

Therefore, the mask 20 of the present invention is characterized by having a circular shape and thus including no corners. That is, the dummy DM of the mask 20 may have a circular shape and include no corners. Because no corners are included, a problem that a different level of force is applied to specific portions of the mask 20 may be solved and stress may be uniformly distributed along the circular edge. As such, the mask 20 may not be warped or distorted, precise pixel alignment may be ensured, and the mask patterns P of 2,000 PPI or higher may be implemented. According to the present invention, pixel deposition may be performed by aligning the circular semiconductor (or silicon) wafer having a low thermal expansion coefficient, with the circular mask 20 on which stress is uniformly distributed along the edge, and thus pixels of about 5 to 10 μm may be deposited.

A plurality of mask patterns P may be formed in the cells C. The mask patterns P are a plurality of pixel patterns P corresponding to red (R), green (G), and blue (B). The mask patterns P may have a side-inclined shape, a tapered shape, or a shape that gradually increases in width in a downward direction. A large number of mask patterns P may be grouped into one display cell C. The display cell C is a region having a diagonal length of about 1 to 2 inches and corresponding to one display. Alternatively, the display cell C may be a region corresponding to a plurality of displays.

The mask patterns P may have a substantially tapered shape, and have a width of several to ten-odd μm, and more specifically, a width of about 5 to 10 μm (i.e., a resolution of 2,000 PPI or higher). The mask patterns P may be formed through laser processing or patterning using a photoresist (PR), but are not limited thereto.

The mask 20 may include a plurality of cells C. The plurality of cells C may be spaced apart from each other by a certain distance in a first direction (e.g., an x-axis direction), and a second direction perpendicular to the first direction (e.g., a y-axis direction). Twenty-one cells C are provided along the first and second directions in FIG. 1, but the number of cells C is not limited thereto. The separators SR may be provided between the cells C. The cells C and the separators SR may be provided at a position corresponding to an opening R of the frame 40. The cells C and the separators SR are provided at a center of the mask 20 compared to the dummy DM.

The edge of the dummy DM may have a circular shape or a shape corresponding to the semiconductor wafer, and define an outer shape of the mask 20. At least portions of the dummy DM may be connected onto the grid sheet 30. Specifically, at least portions of the dummy DM may be attached and connected to at least portions of an edge 31 of the grid sheet 30. The dummy DM and the edge 31 may be attached to each other by forming second welds WB2 therebetween. To attach the mask 20 close to an inner circumference of the edge 31 of the grid sheet 30, the second welds WB2 may be formed closer to the center of the mask 20 compared to first welds WB1.

Referring to FIGS. 1 to 3, the grid sheet 30 may include the edge 31, a plurality of first grids 33, and a plurality of second grids 35. Although the edge 31, the first grids 33, and the second grids 35 are denoted by different names and symbols, the edge 31, the first grids 33, and the second grids 35 are not divided from each other but include the same material and are integrally connected to each other. In other words, the edge 31, the first grids 33, and the second grids 35 are portions of the grid sheet 30 which are simultaneously formed in a process such as rolling or electroforming. In the following description, the edge 31, the first grids 33, and the second grids 35 may be used interchangeably with the grid sheet 30.

The grid sheet 30 may be made of Invar or Super Invar, and the edge 31 may have a circular shape to correspond to the circular semiconductor wafer. To connect the mask 20 onto the grid sheet 30, the grid sheet 30 may have a size at least equal to or greater than that of the mask 20.

The edge 31 may have a shape corresponding to the mask 20, and define an outer shape of the grid sheet 30. The edge 31 may have a circular ring shape. At least portions of the edge 31 may be connected onto the frame 40. The edge 31 and the frame 40 may be attached to each other by forming the first welds WB1 therebetween.

The plurality of first grids 33 may extend in the first direction and include both ends connected to the edge 31. The plurality of second grids 35 may extend in the second direction perpendicular to the first direction to cross the first grids 33, and include both ends connected to the edge 31. The first grids 33 are spaced apart from each other in parallel, and the second grids 35 are also spaced apart from each other in parallel. Because the first and second grids 33 and 35 cross each other on the opening R of the frame 40, empty spaces CR may occur at the intersections in the form of a matrix. These empty spaces CR are spaces where the cells C of the mask 20 are provided, and are referred to as cell regions CR (see FIG. 3).

The mask 20 may be connected onto the grid sheet 30 by forming the second welds WB2 therebetween. The edge 31 of the grid sheet 30 may be in contact with the dummy DM of the mask 20, and the first and second grids 33 and 35 of the grid sheet 30 may be in contact with the separators SR of the mask 20. That is, the first and second grids 33 and 35 may be provided under the separators SR.

Because the grid sheet 30 also has a circular edge shape and includes no corners like the mask 20, a problem that a different level of force is applied to specific portions of the grid sheet 30 may be solved. In addition, stress may be uniformly distributed along the circular edge. As such, the grid sheet 30 may not be warped or distorted. Because the circular mask 20 is connected onto the circular grid sheet 30, stress may be distributed twice. Moreover, because the first and second grids 33 and 35 of the grid sheet 30 are provided under the separators SR of the mask 20 to support the entirety of the mask 20, the cells C and the separators SR of the mask 20 having a very small thickness may be prevented from sagging. Eventually, the mask 20 and the grid sheet 30 may not be warped to ensure precise pixel alignment and implement a high resolution of 2,000 PPI or higher.

Meanwhile, the grid sheet 30 may be connected to the mask 20 further through third welds WB3 in addition to the second welds WB2. Although the edge 31 of the grid sheet 30 is firmly attached to the dummy DM of the mask 20 through the second welds WB2, disconnection may be caused between the separators SR and the first and second grids 33 and 35 at an inner side of the grid sheet 30. As such, the first and second grids 33 and 35 may be firmly attached to the separators SR by forming the third welds WB3 between at least portions thereof. To prevent displacement of the mask patterns P caused by stress applied to surrounding elements due to the formation of weld beads such as the third welds WB3, the third welds WB3 may be formed at the intersections of the first and second grids 33 and 35, which are far from the mask patterns P of the cells C. However, the third welds WB3 are not limited thereto and may be formed on the first and second grids 33 and 35.

The opening R may be formed at the center of the frame 40. The opening R may have a shape corresponding to the edge 31 of the grid sheet 30, to tightly support the grid sheet 30 without sagging or warping. As such, the opening R may have a circular shape.

Meanwhile, although FIG. 1 shows that the circular opening R is formed in the frame 40 having an overall rectangular shape, the frame 40 may have a form in which a ring-shaped second frame including the circular opening R is connected onto a first frame. As long as the first frame is integrally connected to the second frame from below, the first frame may have various shapes, e.g., a circular plate shape, a rectangular plate shape, a circular ring shape, and a rectangular ring shape, the center of which is empty to provide the opening R. The grid sheet 30 may be connected onto the ring-shaped second frame.

Along an outer circumferential direction of the grid sheet 30, a width of the edge 31 attached to the frame 40 may be uniform. That is, an area attached to the frame 40 may be uniform everywhere along the outer circumferential direction of the circular edge 31. Along an outer circumferential direction of the mask 20, a width of the dummy DM attached to the grid sheet 30 may be uniform. That is, an area attached to the edge 31 may be uniform everywhere along the outer circumferential direction of the circular dummy DM. An effect of uniformly distributing stress of the mask 20 and the grid sheet 30 may be obtained because the areas attached along the outer circumferential directions are uniform, and be further enhanced by forming the mask 20 and the grid sheet 30 in a circular shape.

The frame 40 may have a thickness greater than that of the grid sheet 30. The frame 40 is responsible for a total rigidity of the mask-integrated frame 10 and thus may have a thickness of several mm to several cm.

The grid sheet 30 may not be substantially easily produced with a large thickness and, when the grid sheet 30 has an excessively large thickness, the cell regions CR may not be easily formed through etching and a shadow effect may be caused to block paths of organic material sources 600 (see FIG. 21) through the mask 20 in organic light-emitting diode (OLED) pixel deposition. On the other hand, when the grid sheet 30 has an excessively small thickness, a rigidity sufficient to support the mask 20 may not be easily ensured. As such, the grid sheet 30 may have a thickness less than that of the frame 40 and greater than that of the mask 20. The grid sheet 30 may have a thickness of about 20 μm to 50 μm.

To implement the mask patterns P with a resolution of 2,000 PPI or higher, the mask 20 may have a thickness of about 2 μm to 12 μm. When the thickness of the mask 20 is greater than the above-mentioned thickness, a width or a spacing of the mask patterns P having an overall tapered shape may not be controlled appropriately for the above-mentioned resolution.

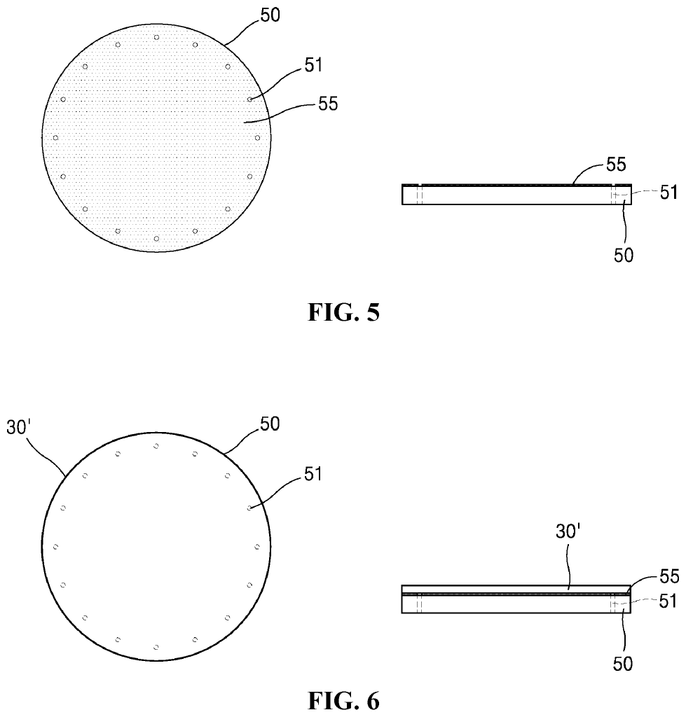

FIGS. 5 to 8 include plan views and cross-sectional views showing a process of manufacturing a first template 50 on which the grid sheet 30 is supported, by adhering a grid metal film 30′ to and forming the grid sheet 30 on the first template 50, according to an embodiment of the present invention.

Referring to FIG. 5, the first template 50 may be prepared. The first template 50 is a medium which may be carried while the grid metal film 30′ or the grid sheet 30 is adhered to and supported on a surface thereof. The first template 50 may be a flat panel having a size equal to or greater than that of the grid metal film 30′ or the grid sheet 30 so as to support the entirety of the grid metal film 30′ or the grid sheet 30, and have a circular shape corresponding to the shape of the grid metal film 30′ or the grid sheet 30.

The first template 50 may use a wafer or a material such as glass, silica, heat-resistant glass, quartz, alumina (Al₂O₃), borosilicate glass, or zirconia.

To allow a laser beam L irradiated from above the first template 50 to reach portions of the edge 31 of the grid sheet 30, the first template 50 may include laser holes 51. The laser holes 51 may be formed in the first template 50 to correspond to the number and positions of the first welds WB1 to be formed between the grid sheet 30 and the frame 40. Because the first welds WB1 may be spaced apart from each other in a circular direction along the edge 31, the laser holes 51 may also be spaced apart from each other in a circular direction along the edge of the first template 50 to correspond to the first welds WB1.

A temporary adhesive member 55 may be formed on a surface of the first template 50. The temporary adhesive member 55 may allow the grid sheet 30 to be temporarily adhered to and supported on the surface of the first template 50 before the grid sheet 30 is attached to the frame 40.

The temporary adhesive member 55 may use an adhesive agent or adhesive sheet which is releasable by applying heat, or use an adhesive agent or adhesive sheet which is releasable by irradiating ultraviolet (UV) light.

For example, the temporary adhesive member 55 may use a liquid wax. The liquid wax may use the same wax used to polish the semiconductor wafer, and is not limited to a particular type. The liquid wax may include a solvent and a resin component for controlling adhesive force or impact resistance mainly related to retention force, e.g., acryl, vinyl acetate, nylon, or various polymers. For example, the temporary adhesive member 55 may use acrylonitrile butadiene rubber (ABR) as the resin component, and use SKYLIQUID ABR-4016 including n-propyl alcohol, as the solvent component. The liquid wax may be spin-coated on the temporary adhesive member 55.

The liquid wax serving as the temporary adhesive member 55 may be reduced in viscosity at a temperature higher than 85° C. to 100° C. and be increased in viscosity and partially solidified at a temperature lower than 85° C., thereby fixing and adhering the grid sheet 30 to the first template 50.

As another example, the temporary adhesive member 55 may use thermal release tape. The thermal release tape may have a form in which a core film such as a polyethylene terephthalate (PET) film is provided in the middle, thermal release adhesives are provided on both surfaces of the core film, and release films are provided on the outsides of the adhesives. Herein, the adhesives provided on both surfaces of the core film may be released at different temperatures.

Then, referring to FIG. 6, the grid metal film 30′ may be adhered onto the first template 50. The liquid wax may be heated to 85° C. or higher, the grid metal film 30′ may be placed in contact with the first template 50, and then the grid metal film 30′ and the first template 50 may be adhered to each other by passing between rollers.

The grid metal film 30′ including one or both surfaces on which surface defect removal and thickness reduction are performed may be used. The surface defect removal and the thickness reduction may also be performed after the grid metal film 30′ is adhered onto the first template 50 as illustrated in FIG. 6. The grid metal film 30′ may be reduced in thickness to about 20 μm to 50 μm due to the surface defect removal and the thickness reduction. Alternatively, the grid metal film 30′ which is already reduced in thickness may be adhered to the first template 50.

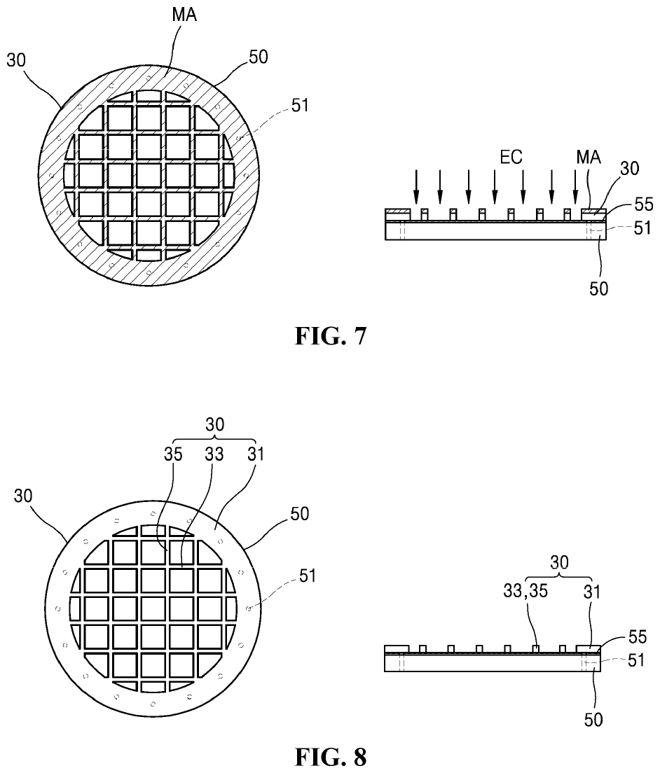

Then, referring to FIG. 7, a patterned insulator MA may be formed on the grid metal film 30′. The insulator MA may be, for example, printed by using a photoresist.

Thereafter, etching EC may be performed on the grid metal film 30′. A method such as dry etching or wet etching may be used without limitation, and portions of the grid metal film 30′ exposed through empty spaces in the insulator MA may be etched as the result of the etching EC. The etched portions of the grid metal film 30′ have a size of about 1 to 2 inches corresponding to a microdisplay, and may be provided as the cell regions CR. After the etching EC, the grid metal film 30′ may serve as the grid sheet 30 including the edge 31 and the first and second grids 33 and 35.

Thereafter, referring to FIG. 8, the insulator MA may be removed to complete the manufacturing of the first template 50 on which the grid sheet 30 is supported.

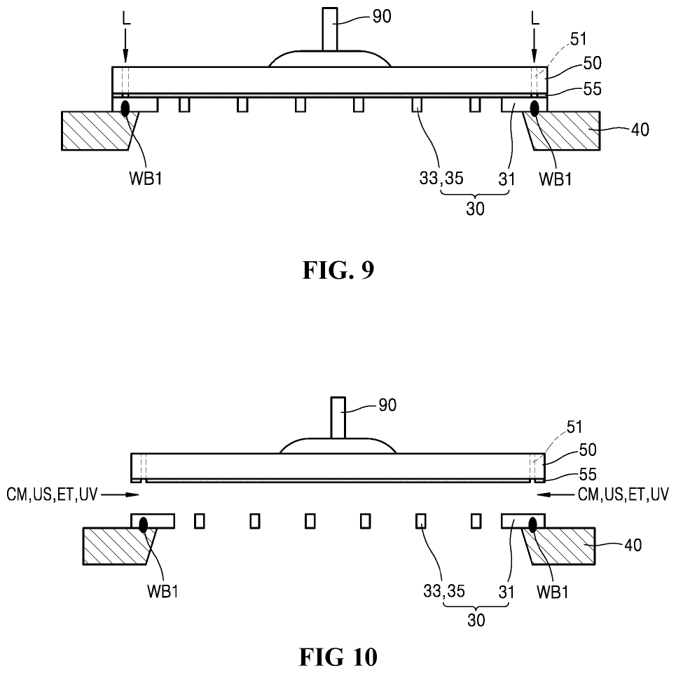

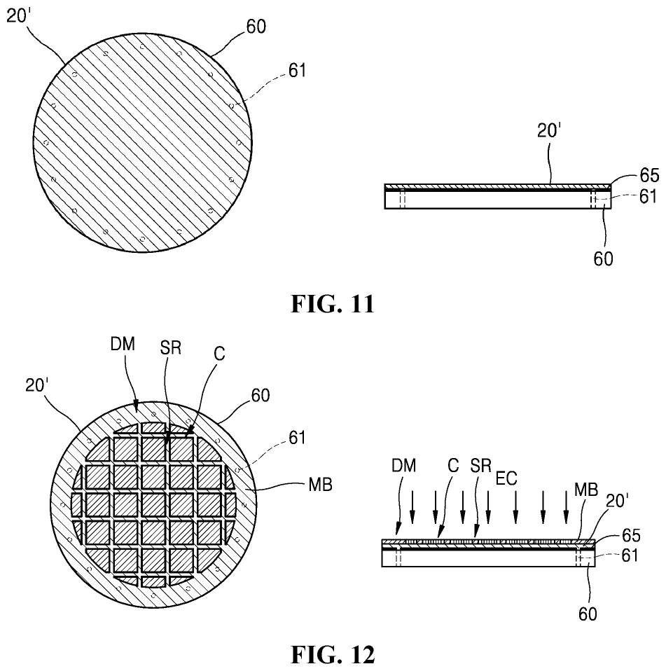

FIGS. 9 and 10 are cross-sectional views showing a process of connecting the grid sheet 30 to the frame 40 by loading, on the frame 40, the first template 50 on which the grid sheet 30 is supported, according to an embodiment of the present invention.

Referring to FIG. 9, the first template 50 on which the grid sheet 30 is adhesively supported may be loaded on the frame 40. The first template 50 may be carried by a chuck 90. For example, a vacuum chuck 90 may carry the first template 50 by sucking a surface opposite to the surface of the first template 50 to which the grid sheet 30 is adhered.

The grid sheet 30 may be aligned in contact with the frame 40. That is, the edge 31 of the grid sheet 30 may be aligned in contact with an upper surface of the frame 40 outside the opening R. The grid sheet 30 may be aligned with the frame 40 by loading the first template 50 on the frame 40. Because the first template 50 presses the grid sheet 30, the grid sheet 30 may be in close contact with the frame 40.

Thereafter, the grid sheet 30 may be attached to the frame 40 through laser welding by irradiating the laser beam L onto the grid sheet 30 to pass through the laser holes 51. Weld beads such as the first welds WB1 may be formed between the laser-welded edge 31 and frame 40, and the first welds WB1 may integrally connect the grid sheet 30 (or the edge 31) to the frame 40.

Then, referring to FIG. 10, after the grid sheet 30 is attached to the frame 40, the first template 50 may be debonded from the grid sheet 30. The first template 50 may be debonded from the grid sheet 30 by performing at least one of heat treatment ET, chemical machining CM, ultrasonic irradiation US, and ultraviolet irradiation UV on the temporary adhesive member 55. For example, when heat of a temperature higher than 85° C. to 100° C. is applied, the viscosity of the temporary adhesive member 55 may be reduced and the adhesive force between the grid sheet 30 and the first template 50 may also be reduced, thereby debonding the first template 50 from the grid sheet 30. As another example, the first template 50 may be debonded from the grid sheet 30 by dissolving or removing the temporary adhesive member 55 by dipping the temporary adhesive member 55 in a chemical material such as isopropyl alcohol (IPA), acetone, or ethanol. As another example, when ultrasonic waves or UV light is irradiated, the adhesive force between the grid sheet 30 and the first template 50 may be reduced and thus the first template 50 may be debonded from the grid sheet 30.

As such, the form in which the grid sheet 30 is connected onto the frame 40 is completed.

FIGS. 11 to 13 include plan views and cross-sectional views showing a process of manufacturing a second template 60 on which the mask 20 is supported, by adhering a mask metal film 20′ and forming the mask patterns P on the second template 60, according to an embodiment of the present invention. In the following description, unless otherwise specified, the second template 60 is substantially the same element as the above-described first template 50 except for the size and shape thereof.

Referring to FIG. 11, the second template 60 may be prepared. Laser holes 61 may be formed in and a temporary adhesive member 65 may be formed on the second template 60. Then, the mask metal film 20′ may be adhered onto the second template 60. A method of adhering the mask metal film 20′ to the second template 60 corresponds to the method of adhering the grid metal film 30′ to the first template 50, which is described above in relation to FIG. 6.

The mask metal film 20′ including one or both surfaces on which surface defect removal and thickness reduction are performed may be used. The surface defect removal and the thickness reduction may also be performed after the mask metal film 20′ is adhered onto the second template 60 as illustrated in FIG. 11. The mask metal film 20′ may be reduced in thickness to about 2 μm to 12 μm due to the surface defect removal and the thickness reduction. Alternatively, the mask metal film 20′ which is already reduced in thickness may be adhered to the second template 60. Particularly, the surface defect removal and the thickness reduction may be considered significantly for the mask metal film 20′ rather than the grid metal film 30′. An Invar film may include irregular grains, and a rolled Invar film includes surface grains non-uniformly stretched in a rolling direction but includes uniform grains in the middle. Therefore, fine and uniform mask patterns P may be formed when the middle portion including uniform grains is used to perform etching.

An insulator (not shown) such as a photoresist may be further provided between a lower surface of the mask metal film 20′ and the temporary adhesive member 65. The insulator may be further formed to prevent an etchant from reaching an interface between the mask metal film 20′ and the temporary adhesive member 65 to damage the temporary adhesive member 65/the second template 60 in the step of FIG. 12, and from further etching the mask metal film 20′ in a horizontal direction at the interface to cause an etching error of the mask patterns P. To have a high resistance against the etchant, the insulator may include at least one of a curable negative photoresist and a negative photoresist including epoxy. For example, an epoxy-based photoresist such as SU-8 or a black matrix photoresist may be used so as to be cured in a process of baking the temporary adhesive member 65 or an insulator MB (see FIG. 12). Although an insulator (not shown) may also be further provided between the temporary adhesive member 55 and the grid metal film 30′ in the above-described step of FIG. 7, because the edge 31 and the first and second grids 33 and 35 are formed on a larger scale compared to the mask patterns P, the significance of the insulator may be low.

Then, referring to FIG. 12, a patterned insulator MB may be formed on the mask metal film 20′. The insulator MB may be, for example, printed by using a photoresist.

Thereafter, etching EC may be performed on the mask metal film 20′. A method such as dry etching or wet etching may be used without limitation, and portions of the mask metal film 20′ exposed through empty spaces in the insulator MB may be etched as the result of the etching EC. The etched portions of the mask metal film 20′ may serve as the mask patterns P, and thus the mask 20 including a plurality of mask patterns P may be manufactured.

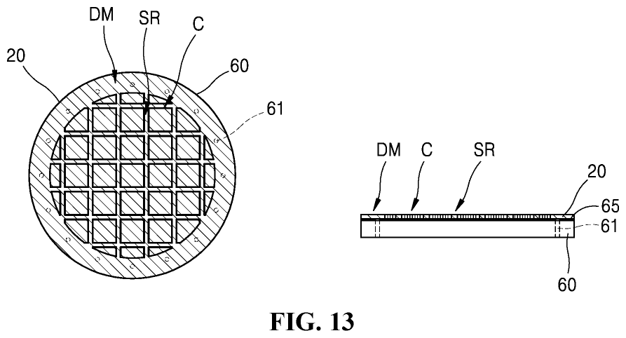

Thereafter, referring to FIG. 13, the insulator MB may be removed to complete the manufacturing of the second template 60 on which the mask 20 including the cells C, the separators SR, and the dummy DM is supported.

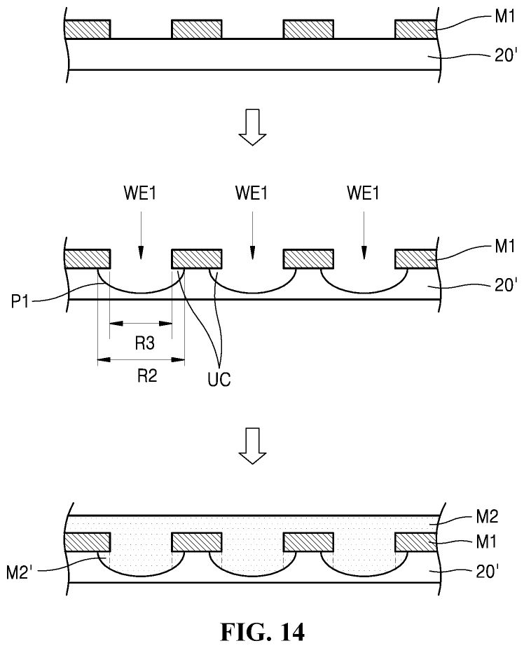

FIGS. 14 to 16 include cross-sectional views showing a process of manufacturing the mask 20 by forming the mask patterns P on the mask metal film 20′, according to an embodiment of the present invention. An etching method for implementing an ultra-high resolution of 2,000 PPI when the mask patterns P are formed by performing the etching EC on the mask metal film 20′ in FIG. 12 will now be described in detail. In the following description, it may be understood that first and second insulators M1 and M2 are included in the insulator MB of FIG. 12 and first and second mask patterns P1 and P2 are included in the mask patterns P. Elements such as the second template 60 are not illustrated for convenience of explanation.

Referring to the first cross-sectional view of FIG. 14, a patterned first insulator M1 may be formed on a surface (i.e., an upper surface) of the mask metal film 20′. The first insulator M1 may be, for example, printed by using a photoresist.

The first insulator M1 may include a black matrix photoresist or a photoresist coated with a metal film thereon. The black matrix photoresist may be a material including a resin black matrix used to form a black matrix of a display panel. The black matrix photoresist may have a better light-blocking effect compared to a normal photoresist. The photoresist coated with the metal film thereon may also have a good effect of blocking light irradiated from above due to the coated metal film.

Then, referring to the second cross-sectional view of FIG. 14, the first mask patterns P1 may be formed in the surface (i.e., the upper surface) of the mask metal film 20′ to a certain depth through wet etching WE1. When the wet etching WE1 is performed, the mask metal film 20′ should not be penetrated. Accordingly, the first mask patterns P1 may be formed in a substantially arc shape without penetrating through the mask metal film 20′. That is, a depth of the first mask patterns P1 may be less than a thickness of the mask metal film 20′.

Because the wet etching WE1 is isotropic, a width R2 of the first mask patterns P1 may not be equal to but be greater than a pattern spacing R3 of the first insulator M1. In other words, because undercuts UC are formed under both sides of the first insulator M1, the width R2 of the first mask patterns P1 may be greater than the pattern spacing R3 of the first insulator M1 by widths of the formed undercuts UC.

Then, referring to the third cross-sectional view of FIG. 14, the second insulator M2 may be formed on the surface (i.e., the upper surface) of the mask metal film 20′. The second insulator M2 may be, for example, printed by using a photoresist. The second insulator M2 needs to remain in spaces where the undercuts UC are formed as described below, and thus may include a positive photoresist.

Because the second insulator M2 is formed on the surface (i.e., the upper surface) of the mask metal film 20′, a portion thereof may be formed on the first insulator M1 and the other portion thereof may be filled in the first mask patterns P1.

The second insulator M2 may use a photoresist diluted in a solvent. When a high-concentration photoresist solution is used to form the second insulator M2 on the mask metal film 20′ and the first insulator M1, the photoresist may react with the photoresist of the first insulator M1 and thus the first insulator M1 may be partially dissolved. Accordingly, in order not to affect the first insulator M1, the second insulator M2 may use a photoresist diluted in a solvent to reduce the concentration thereof.

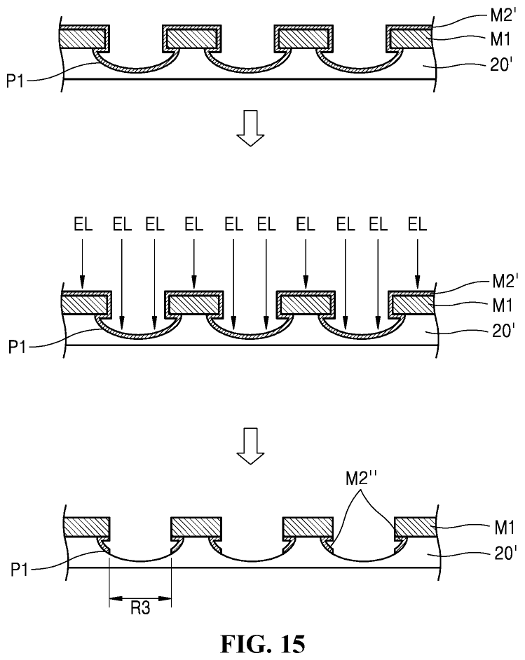

Then, referring to the first cross-sectional view of FIG. 15, baking may be performed to partially volatilize the second insulator M2. Due to the baking, the solvent of the second insulator M2 is volatilized and only the photoresist component remains. Accordingly, a second insulator M2′ may remain like a coated film on the exposed portions of the first mask patterns P1 and the surface of the first insulator M1. The remaining second insulator M2′ may have a thickness less than several μm so as not to affect the pattern spacing R3 of the first insulator M1 or the width R2 of the first mask patterns P1.

Then, referring to the second cross-sectional view of FIG. 15, exposure EL may be performed on the surface (i.e., the upper surface) of the mask metal film 20′. When the exposure EL is performed from above the first insulator M1, the first insulator M1 may serve as a photomask. The first insulator M1 includes a black matrix photoresist or a photoresist coated with a metal film thereon, and thus may have an excellent light-blocking effect. Accordingly, a second insulator M2″ (see the third cross-sectional view of FIG. 15) positioned immediately under the first insulator M1 may not be exposed and the second insulator M2′ other than the second insulator M2″ may be exposed.

Then, referring to the third cross-sectional view of FIG. 15, when development is performed after the exposure EL, the non-exposed second insulator M2″ may remain and the second insulator M2′ other than the second insulator M2″ may be removed. Because the second insulator M2′ is a positive photoresist, the exposed portions thereof may be removed. Spaces where the second insulator M2″ remains may correspond to spaces where the undercuts UC are formed under both sides of the first insulator M1 (see the second cross-sectional view of FIG. 14).

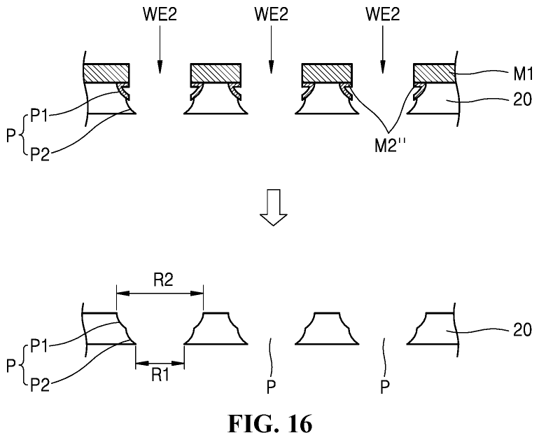

Then, referring to the first cross-sectional view of FIG. 16, wet etching WE2 may be performed on the first mask patterns P1 of the mask metal film 20′. A wet etchant may permeate into spaces between the patterns of the first insulator M1 and spaces in the first mask patterns P1 to perform the wet etching WE2. The second mask patterns P2 may be formed to penetrate through the mask metal film 20′. That is, the second mask patterns P2 may be formed from a bottom surface of the first mask patterns P1 to penetrate through the other surface of the mask metal film 20′. In this case, the second insulator M2″ remains on the first mask patterns P1. The remaining second insulator M2″ may serve as a wet etching mask. That is, the second insulator M2″ prevents the etchant from etching the first mask patterns P1 in a horizontal direction by masking the etchant, and allows the etchant to etch the first mask patterns P1 in a downward direction.

Because the second insulator M2″ is provided in the undercuts UC immediately under the first insulator M1, a pattern spacing of the second insulator M2″ substantially corresponds to the pattern spacing R3 of the first insulator M1. As such, the second mask patterns P2 may be the same as those obtained by performing the wet etching WE2 through the pattern spacing R3 of the first insulator M1. Therefore, a width R1 of the second mask patterns P2 may be less than the width R2 of the first mask patterns P1.

Because the width R1 of the second mask patterns P2 defines a width of pixels, a width corresponding to ultra-high-resolution pixels may be achieved. When the second mask patterns P2 have an excessively large thickness, because the width R1 of the second mask patterns P2 may not be easily controlled to reduce uniformity in the width R1 and the mask patterns P may not have an overall tapered/reverse tapered shape, the thickness of the second mask patterns P2 may be less than the thickness of the first mask patterns P1. The thickness of the second mask patterns P2 may be as close to 0 (zero) as possible.

The consecutively formed first and second mask patterns P1 and P2 may serve as the mask patterns P.

Then, referring to the second cross-sectional view of FIG. 16, the manufacturing of the mask 20 may be completed by removing the first and second insulators M1 and M2. Because the first and second mask patterns P1 and P2 include inclined surfaces and the second mask patterns P2 have a very small height, when the shapes of the first and second mask patterns P1 and P2 are combined, an overall tapered or reverse tapered shape may be obtained.

Because wet etching is performed in an isotropic manner, etched portions naturally exhibit a substantially arc shape. Furthermore, the portions may not be easily wet-etched at exactly the same etch rate, and a deviation thereof may increase when mask patterns are formed to penetrate through the mask metal film 20′ by performing wet etching only once. For example, when two mask patterns formed at different wet etch rates are compared, a difference in upper width (i.e., undercuts) is not large. However, when lower widths of the mask patterns formed to penetrate through the mask metal film 20′ are compared, a difference in lower width is much greater than the difference in upper width due to a slight difference in wet etch rate. This result is because wet etching is performed isotropically. In other words, because a width for determining a pixel size is the lower width rather than the upper width of the mask patterns, compared to a case in which etching is performed once, when the first and second mask patterns P1 and P2 are individually formed by performing etching twice, the lower width dependent on the second mask patterns P2 may be easily controlled.

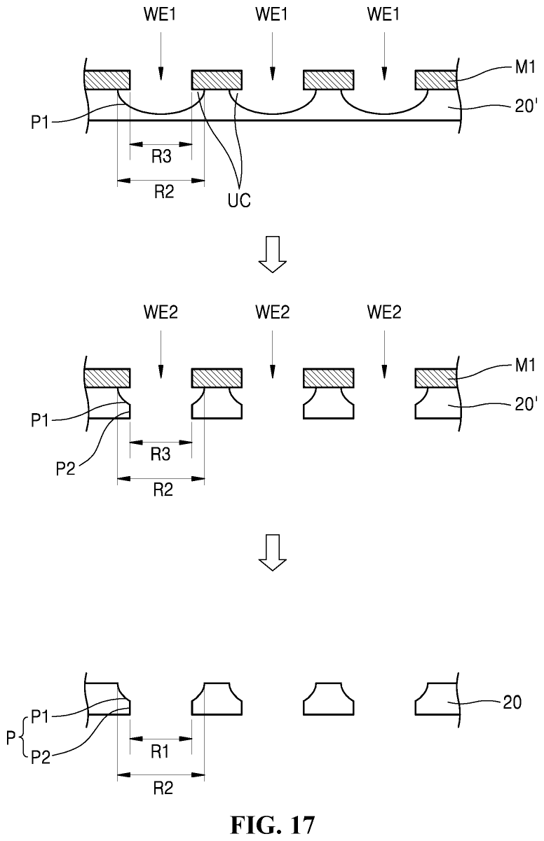

FIG. 17 includes cross-sectional views showing a process of manufacturing the mask 20 by forming the mask patterns P on the mask metal film 20′, according to another embodiment of the present invention.

Referring to the first cross-sectional view of FIG. 17, as in the second cross-sectional view of FIG. 14, the patterned first insulator M1 may be formed on a surface (i.e., an upper surface) of the mask metal film 20′, and then the first mask patterns P1 may be formed in the surface (i.e., the upper surface) of the mask metal film 20′ to a certain depth through wet etching WE1. Because the wet etching WE1 is isotropic, the width R2 of the first mask patterns P1 may not be equal to but be greater than the pattern spacing R3 of the first insulator M1. In other words, because the undercuts UC are formed under both sides of the first insulator M1, the width R2 of the first mask patterns P1 may be greater than the pattern spacing R3 of the first insulator M1 by widths of the formed undercuts UC.

Then, referring to the second cross-sectional view of FIG. 17, the second mask patterns P2 may be formed in the surface (i.e., the upper surface) of the mask metal film 20′ through dry etching DE or laser etching LE. The first insulator M1 may be used as an etching mask for the dry etching DE or the laser etching LE. Although the laser etching LE may use a known technology without limitation, a femtosecond or picosecond laser may be used for precise etching.

The dry etching DE or the laser etching LE is anisotropic and may be performed to a width equal to the pattern spacing R3 of the first insulator M1. Alternatively, the dry etching DE or the laser etching LE may be anisotropic and thus be performed to a width less than the pattern spacing R3 of the first insulator M1. By performing the dry etching DE or the laser etching LE, precise etching may be performed to a desired width. The second mask patterns P2 may be formed to penetrate through the mask metal film 20′. That is, the second mask patterns P2 may be formed from a bottom surface of the first mask patterns P1 to penetrate through the other surface of the mask metal film 20′.

Then, referring to the third cross-sectional view of FIG. 17, the manufacturing of the mask 20 may be completed by removing the first insulator M1. Because the first and second mask patterns P1 and P2 include inclined surfaces and the second mask patterns P2 have a very small height, when the shapes of the first and second mask patterns P1 and P2 are combined, an overall tapered or reverse tapered shape may be obtained. Because the width R1 of the second mask patterns P2 defines a width of pixels, a width corresponding to ultra-high-resolution pixels may be achieved. Through the dry etching DE or the laser etching LE, the width R1 of the second mask patterns P2 may be precisely controlled.

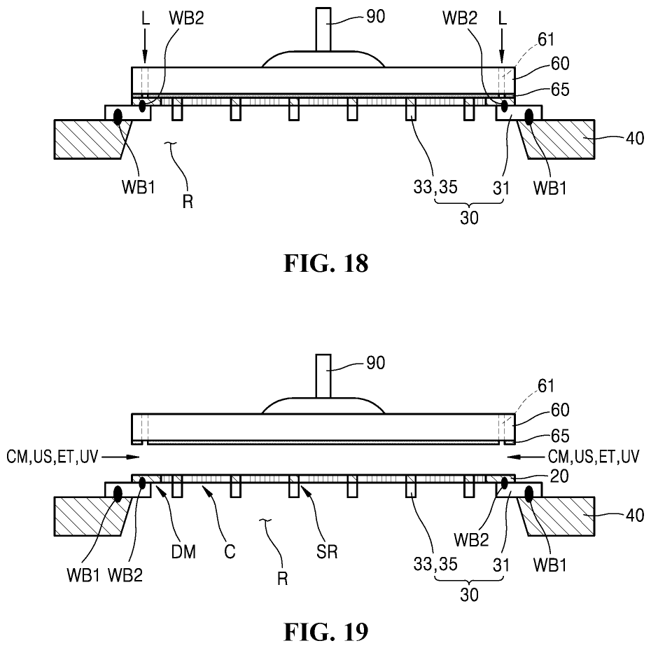

FIGS. 18 and 19 are cross-sectional views showing a process of connecting the mask 20 to the grid sheet 30 by loading, on the grid sheet 30, the second template 60 on which the mask 20 is supported, according to an embodiment of the present invention. A method of connecting the mask 20 to the grid sheet 30 corresponds to the method of connecting the grid sheet 30 to the frame 40, which is described above in relation to FIG. 9.

Referring to FIG. 18, the second template 60 on which the mask 20 is adhesively supported may be loaded on the frame 40. The second template 60 may be carried by the chuck 90. For example, the vacuum chuck 90 may carry the second template 60 by sucking a surface opposite to the surface of the second template 60 to which the mask 20 is adhered.

The mask 20 may be aligned in contact with the grid sheet 30. That is, the dummy DM may be aligned in contact with the edge 31, the separators SR may be aligned in contact with the first and second grids 33 and 35, and the cells C may be aligned with the cell regions CR. The mask 20 may be aligned with the grid sheet 30 by loading the second template 60 on the grid sheet 30. Because the second template 60 presses the mask 20, the mask 20 may be in close contact with the grid sheet 30.

Thereafter, the mask 20 may be attached to the grid sheet 30 through laser welding by irradiating the laser beam L onto the mask 20 to pass through the laser holes 61. Weld beads such as the second welds WB2 may be formed between the laser-welded dummy DM and edge 31, and the second welds WB2 may integrally connect the mask 20 (or the dummy DM) to the grid sheet 30.

Then, referring to FIG. 19, after the mask 20 is attached to the grid sheet 30, the second template 60 may be debonded from the mask 20. The second template 60 may be debonded from the mask 20 by performing at least one of heat treatment ET, chemical machining CM, ultrasonic irradiation US, and ultraviolet irradiation UV on the temporary adhesive member 65.

As such, the form in which the mask 20 is connected onto the grid sheet 30 is completed. In addition, the manufacturing of the mask-integrated frame 10 including the mask 20, the grid sheet 30, and the frame 40 is completed.

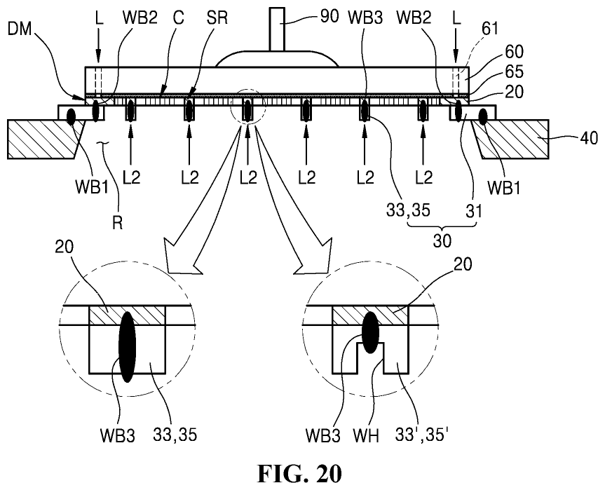

FIG. 20 is a cross-sectional view showing connection between the mask 20 and the grid sheet 30, according to various embodiments of the present invention.

As described above, the grid sheet 30 may be connected to the mask 20 further through the third welds WB3 in addition to the second welds WB2. Unlike the first and second welds WB1 and WB2, the third welds WB3 may be formed by irradiating a laser beam L2 from below (or through the opening R). Although the first and second welds WB1 and WB2 may receive the laser beam L through the laser holes 51 and 61 of the first and second template 50 and 60, the first and second grids 33 and 35 in which the third welds WB3 are to be formed are blocked by the second template 60. Moreover, because the separators SR of the mask 20 on the first and second grids 33 and 35 are substantially in contact with the target substrate 900 such as a semiconductor wafer in OLED pixel deposition, when weld beads are formed by irradiating a laser beam from above, the third welds WB3 may protrude upward and cause disconnection between the mask 20 and the target substrate 900. Therefore, by irradiating the laser beam L2 from below, the third welds WB3 may protrude downward to prevent disconnection between the mask 20 and the target substrate 900.

According to an embodiment, as shown in the left magnified view of FIG. 20, the third welds WB3 may be directly formed in the mask 20 and the first and second grids 33 and 35.

According to another embodiment, as shown in the right magnified view of FIG. 20, first and second grids 33′ and 35′ including welding holes WH may be provided. The welding holes WH may be formed when the etching EC is performed on the grid metal film 30′ in FIG. 7.

Meanwhile, because a surface opposite to a surface of the mask 20 where the third welds WB3 are to be formed is supported by the second template 60 while the third welds WB3 are being formed, the third welds WB3 may be formed stably. In addition, the second template 60 may prevent the third welds WB3 from protruding from the opposite surface of the mask 20 while the third welds WB3 are being formed.

According to another embodiment of the present invention, the third welds WB3 may be formed by irradiating the laser beam L2 from below in the state shown in FIG. 20. However, the third welds WB3 may also be formed by flipping the frame 40/the grid sheet 30/the mask 20 (and the second template 60) and then irradiating the laser beam L2 from above.

Because the welding holes WH are formed in the first and second grids 33′ and 35′, portions of the first and second grids 33′ and 35′ in which the third welds WB3 are to be substantially formed may have a small thickness. As such, the third welds WB3 may be formed using a low-power laser beam L2 to attach the mask 20 to the first and second grids 33′ and 35′. Furthermore, because the third welds WB3 are formed to a smaller size, stress applied to the mask 20 and the first and second grids 33′ and 35′ may be reduced and thus displacement of the mask patterns P may be prevented.

Because the mask 20 capable of implementing an ultra-high resolution of about 2,000 PPI has a thickness less than about 12 μm, a tension may vary depending on a region of the very thin mask 20. Moreover, it is not easy to apply a uniform tension all over by clipping and tightening the mask 20. To solve the above problem, according to the present invention, the grid sheet 30 is formed in a circular shape, and is attached onto the frame 40 by controlling only the first template 50 without directly clipping and applying tensile force to the grid sheet 30. Thereafter, the mask 20 is formed in a circular shape, and is attached onto the grid sheet 30 by controlling only the second template 60 without directly clipping and applying tensile force to the mask 20. Due to the above-described double template process, the grid sheet 30 and the mask 20, which are elements of the mask-integrated frame 10, may be tightly connected to each other without applying tensile force based on direct clipping and, at the same time, precise alignment of the mask cells C and the mask patterns P may be ensured. Therefore, high-resolution pixels of 2,000 PPI or higher may be implemented.

FIG. 21 is a cross-sectional view of an OLED pixel deposition apparatus 200 using the mask-integrated frame 10, according to an embodiment of the present invention.

Referring to FIG. 21, the OLED pixel deposition apparatus 200 includes a magnet plate 300 accommodating a magnet 310 and provided with a cooling water line 350, and a deposition source supplier 500 for supplying organic material sources 600 from below the magnet plate 300.

The target substrate 900, e.g., a glass substrate, on which the organic material sources 600 are to be deposited may be provided between the magnet plate 300 and the deposition source supplier 500. The mask-integrated frame 10 for depositing the organic material sources 600 in pixels may be placed in close contact with or very close to the target substrate 900. The magnet 310 may form a magnetic field and the mask-integrated frame 10 may be in close contact with the target substrate 900 due to attractive force caused by the magnetic field.

The deposition source supplier 500 may reciprocate horizontally to supply the organic material sources 600, and the organic material sources 600 supplied from the deposition source supplier 500 may be deposited on a surface of the target substrate 900 through the mask patterns P provided in the mask-integrated frame 10. The organic material sources 600 deposited through the mask patterns P of the mask-integrated frame 10 may serve as OLED pixels 700.

Because the mask patterns P have a side-inclined shape (i.e., a tapered shape), non-uniform deposition of the OLED pixels 700 due to a shadow effect may be prevented by the organic material sources 600 passing along inclined directions.

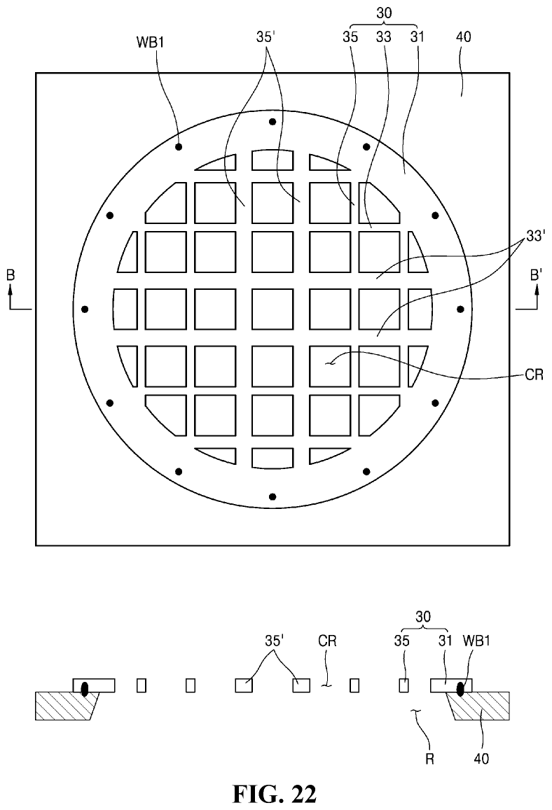

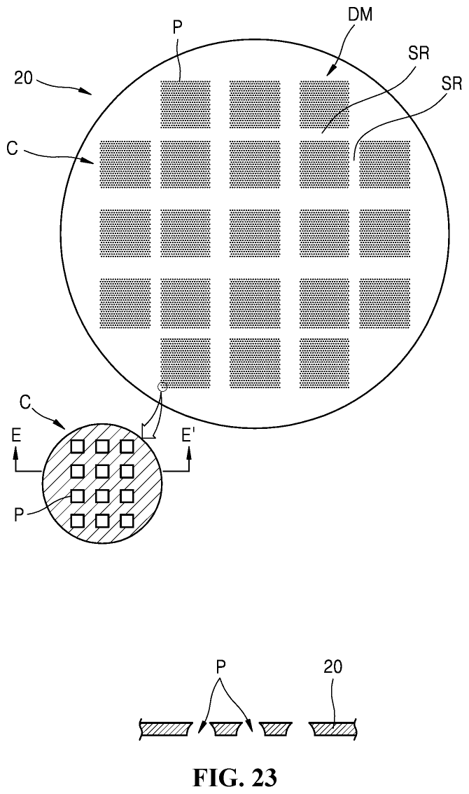

FIG. 22 includes a plan view and a B-B′ side cross-sectional view showing connection between the grid sheet 30 and the frame 40, according to another embodiment of the present invention. FIG. 23 includes a plan view and an E-E′ side cross-sectional view of the mask 20 according to another embodiment of the present invention.

Referring to FIG. 22, in the grid sheet 30 according to another embodiment of the present invention, specific first and second grids 33′ and 35′ from among the first and second grids 33 and 35 may have a width different from that of the other first and second grids 33 and 35. According to an embodiment, first grids 33′ provided in the middle from among a plurality of first grids 33 and second grids 35′ provided in the middle from among a plurality of second grids 35 may have a larger width. Parts where the first and second grids 33′ and 35′ cross each other may have a large width in a ‘+’ shape. According to another embodiment, the middle and a few adjacent first and second grids 33′ and 35′ may have a larger width. According to still another embodiment, first and second grids 33′ and 35′ in a specific partial region of the whole grid sheet 30 may have a larger width.

For example, when the width of the first and second grids 33 and 35 is 1, the width of the specific first and second grids 33′ and 35′ may be 3. Due to the larger width, the specific first and second grids 33′ and 35′ may have a rigidity higher than that of the other first and second grids 33 and 35.

Referring to FIG. 23, the separators SR of the mask 20 may have widths corresponding to those of the first and second grids 33 and 35 and the specific first and second grids 33′ and 35′ of the grid sheet 30. From a different point of view, the cells C of the mask 20 may be formed to correspond to the cell regions CR of the grid sheet 30. As such, even when the mask 20 is connected onto the grid sheet 30, middle portions of the mask 20 corresponding to the first and second grids 33′ and 35′ may be stably supported by and connected onto the grid sheet 30 without being sagged, wrinkled, or warped due to the self-weight.

As described above, according to the present invention, ultra-high-resolution pixels of a microdisplay may be implemented.

In addition, according to the present invention, stability of pixel deposition may be improved by ensuring precise mask alignment.

However, the scope of the present invention range is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A mask-integrated frame used to deposit organic light-emitting diode (OLED) pixels on a semiconductor wafer, the mask-integrated frame comprising:
a frame comprising an opening;
a grid sheet connected onto the frame, having a circular edge, and comprising grids provided on at least the opening of the frame; and
a mask connected onto the grid sheet, having a circular shape, and comprising mask patterns.

2. The mask-integrated frame of claim 1, wherein the grid sheet comprises:
an edge connected onto the frame;
a plurality of first grids extending in a first direction and comprising both ends connected to the edge; and
a plurality of second grids extending in a second direction perpendicular to the first direction to cross the first grids, and comprising both ends connected to the edge.

3. The mask-integrated frame of claim 2, wherein first welds are formed in at least portions of the edge to attach the grid sheet to the frame.

4. The mask-integrated frame of claim 2, wherein the mask comprises:
a dummy connected onto the grid sheet;
a plurality of cells provided at a center of the mask compared to the dummy, and comprising a plurality of mask patterns; and
separators provided at the center of the mask compared to the dummy, and provided between the plurality of cells.

5. The mask-integrated frame of claim 4, wherein second welds are formed in at least portions of the dummy to attach the mask to the grid sheet.

6. The mask-integrated frame of claim 4, wherein the first and second grids are provided under the separators.

7. The mask-integrated frame of claim 6, wherein third welds are formed in at least portions of the first and second grids to attach the first and second grids to the separators.

8. The mask-integrated frame of claim 7, wherein the third welds are formed to protrude from a surface opposite to a surface where at least the first and second grids are in contact with the separators, and
wherein welding holes are formed from the opposite surface in the first and second grids where the third welds are to be formed.

9. The mask-integrated frame of claim 1, wherein the mask has a thickness of 2 μm to 12 μm, and the grid sheet has a thickness of 20 μm to 50 μm.

10. The mask-integrated frame of claim 1, wherein the mask patterns comprise first mask patterns at upper portions and second mask patterns at lower portions,
wherein the first mask patterns have a thickness greater than a thickness of the second mask patterns, and
wherein both side surfaces of the first and second mask patterns have a curvature.

11. The mask-integrated frame of claim 2, wherein specific first and second grids from among the first and second grids have a width greater than that of the other first and second grids.

12. A method of manufacturing a mask-integrated frame used to deposit organic light-emitting diode (OLED) pixels on a semiconductor wafer, the method comprising:
(a) connecting a grid sheet having a circular edge, onto a frame comprising an opening, wherein the grid sheet comprises grids provided on at least the opening of the frame; and
(b) connecting a mask having a circular shape and comprising mask patterns, onto the grid sheet.

13. The method of claim 12, wherein the grid sheet comprises:
an edge connected onto the frame;
a plurality of first grids extending in a first direction and comprising both ends connected to the edge; and
a plurality of second grids extending in a second direction perpendicular to the first direction to cross the first grids, and comprising both ends connected to the edge.

14. The method of claim 12, wherein the step (a) comprises:
(a1) placing the grid sheet in contact with the frame by loading, on the frame, a first template to which the grid sheet is adhered; and
(a2) attaching the grid sheet to the frame by irradiating a laser beam onto at least portions of a region where the grid sheet is in contact with the frame.

15. The method of claim 14, wherein, in the step (a1), the first template to which the grid sheet is adhered is provided by:
(1) adhering a grid metal film onto the first template comprising a surface on which a temporary adhesive member is formed; and
(2) forming the grids by etching the grid metal film.

16. The method of claim 12, wherein the mask comprises:
a dummy connected onto the grid sheet;
a plurality of cells provided at a center of the mask compared to the dummy, and comprising a plurality of mask patterns; and
separators provided at the center of the mask compared to the dummy, and provided between the plurality of cells.

17. The method of claim 12, wherein the step (b) comprises:
(b1) placing the mask in contact with the grid sheet by loading, on the grid sheet, a second template to which the mask is adhered; and
(b2) attaching the mask to the grid sheet by irradiating a laser beam onto at least portions of a region where the mask is in contact with the grid sheet.

18. The method of claim 17, wherein, in the step (b1), the second template to which the mask is adhered is provided by:
(1) adhering a mask metal film onto the second template comprising a surface on which a temporary adhesive member is formed; and
(2) forming a plurality of mask patterns by etching the mask metal film.

19. The method of claim 16, further comprising attaching at least portions of the grids to the separators by irradiating a laser beam onto a surface opposite to a surface where the grids are in contact with the separators.

20. The method of claim 15, wherein the step (2) further comprises:
forming welding holes in the grids; and
placing a surface of the grids opposite to a surface where the welding holes are formed, in contact with the mask, and attaching at least portions of the grids to the mask by irradiating a laser beam from the surface where the welding holes are formed.
